(19) United States
(12) Patent Application Publication
(10) Pub. No.: US 2026/0152839 A1
(43) Pub. Date: Jun. 4, 2026

(54) MASK, METHOD OF MANUFACTURING THE MASK, AND ELECTRONIC DEVICE

(71) Applicant: Samsung Display Co., LTD., Yongin-si (KR)

(72) Inventors: Jeong Kuk KIM, Yongin-si (KR); Duck Jung LEE, Yongin-si (KR); Sug Woo JUNG, Yongin-si (KR); Sung Won CHO, Yongin-si (KR); Jun Ho JO, Yongin-si (KR)

(21) Appl. No.: 19/253,773

(22) Filed: Jun. 28, 2025

(30) Foreign Application Priority Data
Dec. 2, 2024 (KR) 10-2024-0176837

(51) Int. Cl. C23C 14/04; H10K 59/12; H10K 71/16

(52) U.S. Cl. CPC C23C 14/042; H10K 59/12; H10K 71/166

(57) ABSTRACT

A mask includes a first frame, where first openings are defined through the first frame, and second frames respectively arranged in the first openings, where second openings smaller than the first openings are defined through each of the second frames. The first frame includes a (1-1)th frame portion and a (1-2)th frame portion arranged on the (1-1)th frame portion, and each of the second frames includes a (2-1)th frame portion in a lattice pattern and a (2-2)th frame portion arranged on the (2-1)th frame portion. The (1-1)th frame portion and the (2-1)th frame portion include a first material, and the (1-2)th frame portion and the (2-2)th frame portion include a second material different from the first material.

This application claims priority to Korean Patent Application No. 10-2024-0176837, filed on Dec. 2, 2024, and all the benefits accruing therefrom under 35 U.S.C. §119, the content of which in its entirety is herein incorporated by reference.

### BACKGROUND

### 1. Field

Embodiments of the invention generally relate to a mask, a method of manufacturing the mask, and an electronic device.

### 2. Description of the Related Art

Displays may be manufactured through a variety of processes. For example, a deposition process may be used in a display manufacturing process. In the deposition process for manufacturing a display, a mask which adheres to a substrate for deposition of an organic material may be used.

### SUMMARY

Embodiments provide a method of manufacturing a mask that is easy to form an inverted tapered shape and an inverted taper angle, and has increased strength and a decreased degree of warpage, and a method of manufacturing the mask.

Embodiments provide a method of manufacturing a display device using the mask, and an electronic device including the display device.

In accordance with an embodiment of the invention, a mask includes: a first frame, where first openings are defined through the first frame, and second frames respectively arranged in the first openings, where second openings smaller than the first openings are defined through each of the second frames. In such an embodiment, the first frame includes a (1-1)th frame portion and a (1-2)th frame portion arranged on the (1-1)th frame portion. In such an embodiment, each of the second frames includes a (2-1)th frame portion in a lattice pattern and a (2-2)th frame portion arranged on the (2-1)th frame portion. In such an embodiment, the (1-1)th frame portion and the (2-1)th frame portion include a first material, and the (1-2)th frame portion and the (2-2)th frame portion include a second material different from the first material.

In an embodiment, the first material may be silicon, and the second material may be a silicon nitride.

In an embodiment, in a cross-section, the (2-2)th frame portion may have a rectangular shape.

In an embodiment, in the cross-section, a width of the (2-1)th frame portion may increase as being away from the (2-2)th frame portion in a thickness direction of the mask.

In an embodiment, in the cross-section, the (2-1)th frame portion may have an inverted tapered shape.

In an embodiment, an inverted taper angle of the (2-1)th frame portion may be greater than about 90°.

In an embodiment, in the cross-section, the (2-1)th frame portion may have an inverted triangle shape.

In an embodiment, a width of an upper surface of the (2-1)th frame portion facing a lower surface of the (2-2)th frame portion may be smaller than a width of the lower surface of the (2-2)th frame portion.

In an embodiment, a thickness of the (2-1)th frame portion may be about 1 μm or greater.

In an embodiment, a thickness of each of the (1-2)th frame portion and the (2-2)th frame portion may be about 1 μm or less.

In an embodiment, the mask may further include a third first frame arranged under the third first frame portion, where the third first frame may include the second material.

In accordance with an embodiment of the invention, a method of manufacturing a mask includes: forming a layer on a base substrate, forming a (1-2)th frame portion and (2-2)th frame portions including openings by etching the layer, forming patterns having widths increasing as being away from an upper surface of the base substrate in a thickness direction of the base substrate in a cross-section by etching the upper surface of the base substrate, forming (2-1)th frame portions and an oxide layer surrounding the (2-1)th frame portions by oxidizing the patterns, forming a (1-1)th frame portion by etching a lower surface of the base substrate, and removing the oxide layer.

In an embodiment, the base substrate may include silicon, and the layer may include a silicon nitride.

In an embodiment, a thickness of the layer may be about 1 micrometer (μm) or less.

In an embodiment, a thickness of each of the patterns may be about 1 μm or greater.

In an embodiment, the patterns may have an inverted tapered shape in a cross-section.

In an embodiment, inverted taper angles of the patterns may be greater than about 90°.

In an embodiment, the oxide layer may surround side surfaces of the (2-1)th frame portions.

In an embodiment, in the cross-section, the patterns may have an inverted triangle shape.

In an embodiment, the oxide layer may surround side surfaces and lower surfaces of the (2-1)th frame portions.

In an embodiment, a thickness of the oxide layer may be in a range of about 1000 angstroms to about 10000 angstroms.

In accordance with an embodiment of the invention, a method of manufacturing a display device includes: forming a pixel circuit layer on a substrate, and forming a light-emitting device on the pixel circuit layer. In such an embodiment, the forming the light-emitting device includes depositing an emission layer by using a mask. In such an embodiment, the mask includes a first frame, where first openings are defined through the first frame, and second frames respectively arranged in the first openings, where second openings smaller than the first openings are defined through each of the second frames. In such an embodiment, the first frame includes a (1-1)th frame portion and a (1-2)th frame portion arranged on the (1-1)th frame portion. In such an embodiment, each of the second frames includes a (2-1)th frame portion in a lattice pattern and a (2-2)th frame portion arranged on the (2-1)th frame portion. In such an embodiment, the (1-1)th frame portion and the (2-1)th frame portion include a first material. In such an embodiment, the (1-2)th frame portion and the (2-2)th frame portion include a second material different from the first material.

In accordance with an embodiment of the invention, an electronic device includes: a processor, and a display device including an emission layer. In such an embodiment, the display device displays an image in response to control of the processor. In such an embodiment, the emission layer is deposited by the mask described above.

### BRIEF DESCRIPTION OF THE DRAWINGS

The above and other features of embodiments of the invention will become more apparent by describing in further detail embodiments thereof with reference to the accompanying drawings, in which:

FIG. 1 is a plan view of a mask according to an embodiment.

FIG. 2 is a cross-sectional view taken along line I-I′ of FIG. 1 according to an embodiment.

FIG. 3 is a cross-sectional view of a mask according to an embodiment.

FIG. 4 is a cross-sectional view of a mask according to an embodiment.

FIGS. 5 to 10 are diagrams illustrating a method of manufacturing a mask according to an embodiment.

FIGS. 11 to 13 are diagrams illustrating a method of manufacturing a mask according to an embodiment.

FIGS. 14 to 19 are diagrams illustrating a method of manufacturing a mask according to an embodiment.

FIG. 20 is a plan view of a display device according to an embodiment.

FIG. 21 is a plan view of sub-pixels according to an embodiment.

FIG. 22 is a cross-sectional view taken along line II-II′ of FIG. 21 according to an embodiment.

FIG. 23 is a flowchart illustrating a method of manufacturing a display device according to an embodiment.

FIG. 24 is a block diagram of an electronic device according to an embodiment.

FIG. 25 shows schematic views of various embodiments of an electronic device.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

Throughout the specification, in a case in which a portion is “connected” to another portion, the case includes not only a case in which the portion is directly connected but also a case in which the portion is indirectly connected with one or more other elements interposed therebetween. Terms used herein are for describing specific embodiments and are not intended to limit the present disclosure.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. “At least one of X, Y, and Z” and “at least one selected from X, Y, and Z” may be interpreted as one X, one Y, one Z, or any combination of two or more of X, Y, and Z (for example, XYZ, XY, YZ, and XZ). It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Spatially relative terms, such as “under,” “on,” and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions of on and under. In addition, the device may face in other directions (for example, rotated 90 degrees or in other directions) and, thus, the spatially relative terms used herein are interpreted according thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

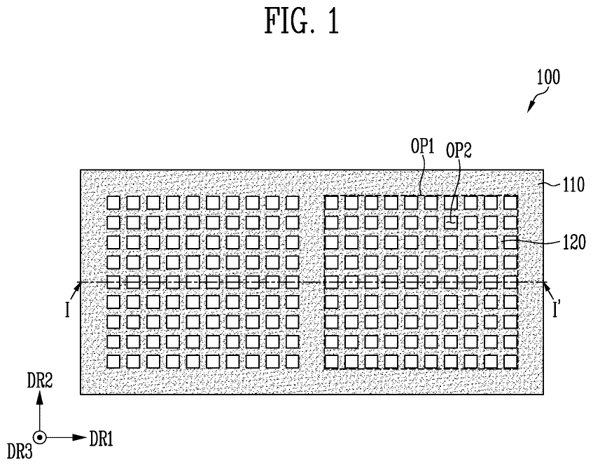

FIG. 1 is a plan view of a mask 100 according to an embodiment.

Referring to FIG. 1, an embodiment of the mask 100 may be used for manufacturing a display device. For example, a deposition material (e.g., a light-emitting material) evaporated from a deposition source may pass through the mask 100 and be deposited on an object (e.g., a substrate) in a predetermined pattern. However, the embodiments are not necessarily limited thereto.

In an embodiment, the mask 100 may include a first frame 110 and second frames 120.

The first frame 110 may form a basic structure of the mask 100. In an embodiment, for example, the first frame 110 may have a rectangular shape with a long side extending in a first direction DR1 and a short side extending in a second direction DR2. Here, a third direction DR3 may be a direction perpendicular to the first direction DR1 and the second direction DR2, or may be a thickness direction of the first frame 110. However, embodiments are not necessarily limited thereto. In an embodiment, for example, the first frame 110 may have various shapes such as a circle, a polygon, and the like. The first frame 110 may be provided with (or define) first openings OP1. In an embodiment, as shown in FIG. 1, the first frame 110 may be provided with two first openings OP1, but embodiments are not necessarily limited thereto. The number of the first openings OP1 may vary according to the size, use, etc. of the mask 100.

The second frames 120 may be arranged in the first openings OP1 of the first frame 110, respectively. In an embodiment, for example, the second frames 120 may be arranged in the first openings OP1 of the first frame 110 in a lattice (or mesh) form, respectively. Although FIG. 1 shows an embodiment where two second frames 120 are provided, embodiments are not necessarily limited thereto. The number of the second frames 120 may vary according to the number of first openings OP1. The second frames 120 may be provided with (or define) second openings OP2 which are smaller than the first openings OP1. The deposition material as described above may pass through the second openings OP2 of the second frames 120 and be deposited on an object.

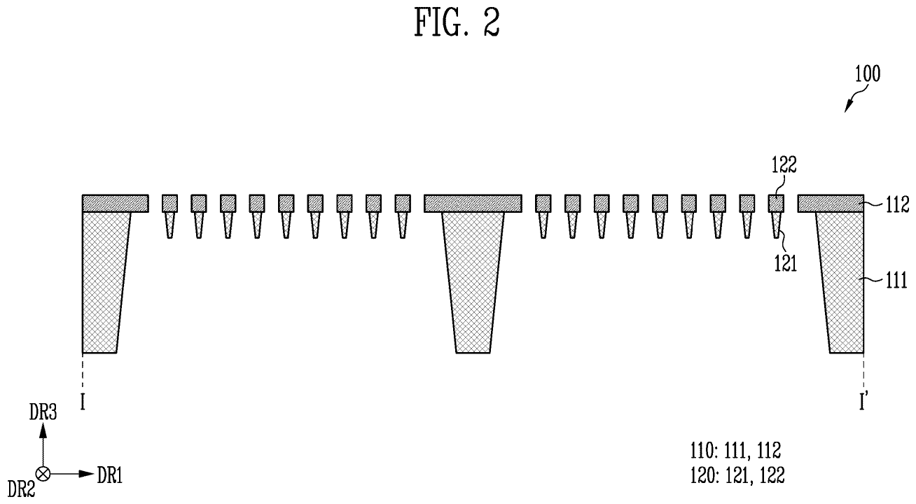

FIG. 2 is a cross-sectional view taken along line I-I′ of FIG. 1 according to an embodiment.

Referring to FIG. 2, in an embodiment, the first frame 110 of the mask 100 may include a (1-1)th frame portion (hereinafter, will be referred to as “(1-1)th frame portion”) 111 and a (1-2)th frame portion (hereinafter, will be referred to as “(1-2)th frame portion”) 112.

The (1-1)th frame portion 111 may support the (1-2)th frame portion 112. The (1-2)th frame portion 112 may be arranged on the (1-1)th frame portion 111. A width of an upper surface of the (1-1)th frame portion 111 may be different from that of a lower surface of the (1-2)th frame portion 112. The width may be a length measured in the first direction DR1. In an embodiment, for example, the width of the upper surface of the (1-1)th frame portion 111 facing the lower surface of the (1-2)th frame portion 112 may be smaller than a width of the lower surface of the (1-2)th frame portion 112. That is, the (1-2)th frame portion 112 may protrude in the first direction DR1 (or a direction opposite to the first direction DR1) compared to the (1-1)th frame portion 111.

The (1-1)th frame portion 111 and the (1-2)th frame portion 112 may include different materials from each other. The (1-1)th frame portion 111 may include or be formed of a first material. In an embodiment, for example, the first material may be silicon (Si). The (1-2)th frame portion 112 may include or be formed of a second material different from the first material. In an embodiment, for example, the second material may be silicon nitride (SiNₓ).

Each of the second frames 120 of the mask 100 may include a (2-1)th frame portion (hereinafter, will be referred to as “(2-1)th frame portion”) 121 and a (2-2)th frame portion (hereinafter, will be referred to as “(2-2)th frame portion”) 122.

The (2-1)th frame portion 121 may support the (2-2)th frame portion 122. The (2-2)th frame portion 122 may be arranged on the (2-1)th frame portion 121. The (2-1)th frame portion 121 and the (2-2)th frame portion 122 may have a lattice (or mesh) shape. A width of an upper surface of the (2-1)th frame portion 121 may be different from a width of a lower surface of the (2-2)th frame portion 122. In an embodiment, for example, the width of the upper surface of the (2-1)th frame portion 121 facing the lower surface of the (2-2)th frame portion 122 may be smaller than the width of the lower surface of the (2-2)th frame portion 122. That is, the (2-2)th frame portion 122 may protrude in the first direction DR1 (or a direction opposite to the first direction DR1) compared to the (2-1)th frame portion 121.

The (2-1)th frame portion 121 and the (2-2)th frame portion 122 may include different materials from each other. The (2-1)th frame portion 121 may include or be formed of the first material. In an embodiment, for example, the first material may be silicon (Si). The (2-2)th frame portion 122 may include or be formed of the second material different from the first material. In an embodiment, for example, the second material may be silicon nitride (SiNₓ).

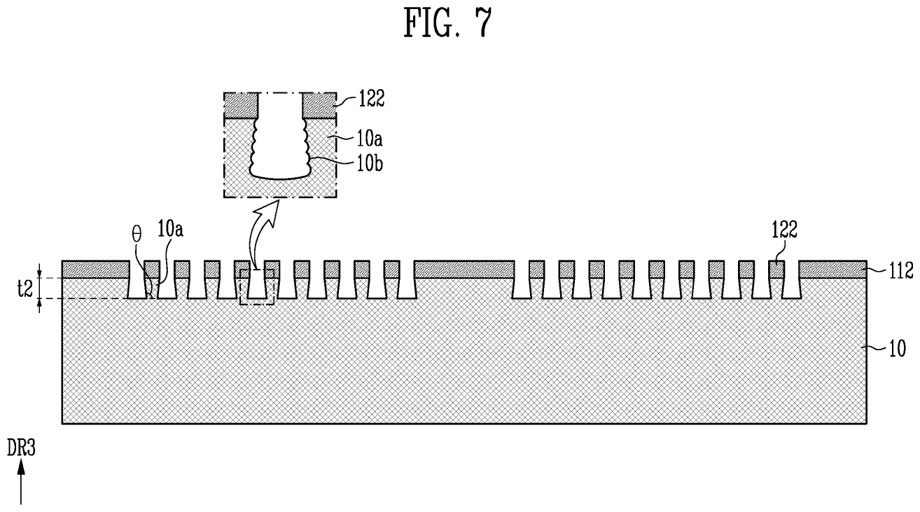

In a cross-section, the width of the (2-1)th frame portion 121 may increase as being away from the (2-2)th frame portion 112 in the third direction DR3 (or the thickness direction). In an embodiment, for example, the (2-1)th frame portion 121 may have an inverted tapered shape in cross-section. A detailed description thereof will be provided below with reference to FIG. 7. In a cross-section, the (2-2)th frame portion 122 may have a rectangular shape. In an embodiment, for example, the width of the (2-2)th frame portion 122 may be constant in the third direction DR3 without any substantial increase or decrease in the third direction DR3. However, embodiments are not necessarily limited thereto.

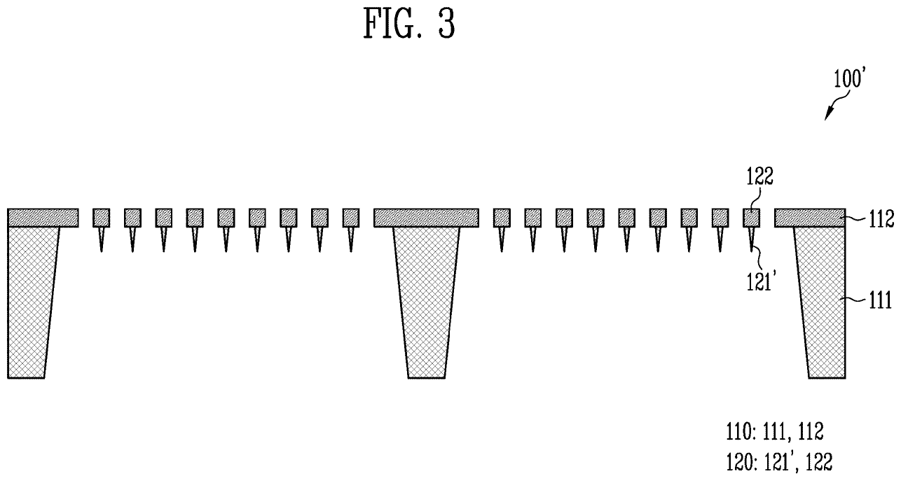

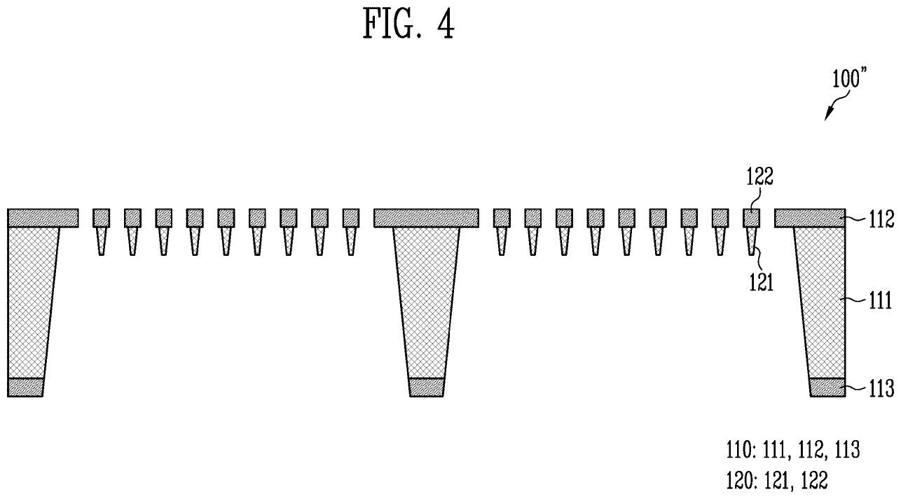

FIG. 3 is a cross-sectional view of a mask 100′ according to an embodiment. In FIG. 3, the same or like elements shown in FIG. 4 are labeled with the same reference characters as used above to describe the embodiment of the mask shown in FIGS. 1 to 2, any repetitive detailed description thereof will be omitted or simplified, and the description will be focused on the differences.

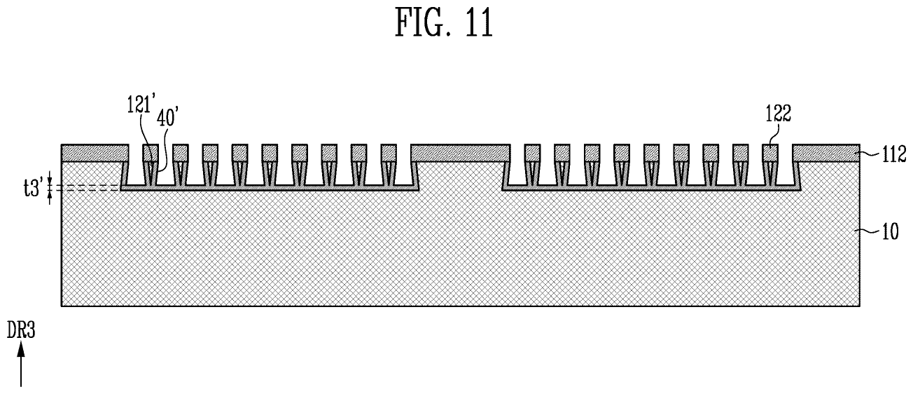

Referring to FIG. 3, in an embodiment, a (2-1)th frame portion 121′ of the mask 100′ may have an inverted triangle shape in cross-section. A width of an upper surface of the (2-1)th frame portion 121′ facing the lower surface of the (2-2)th frame portion 122 may decrease compared to FIG. 1. In an embodiment, for example, the width of the upper surface of the (2-1)th frame portion 121′ may be smaller than that of the upper surface of the (1-2)th frame portion 121 shown in FIG. 1. A detailed description thereof will be provided below with reference to FIG. 11.

FIG. 4 is a cross-sectional view of a mask 100″ according to an embodiment. In FIG. 4, the same or like elements shown in FIG. 4 are labeled with the same reference characters as used above to describe the embodiment of the mask shown in FIGS. 1 to 2, any repetitive detailed description thereof will be omitted or simplified, and the description thereof will be focused on the differences.

Referring to FIG. 4, in an embodiment, the first frame 110 of the mask 100″ may include the (1-1)th frame portion 111, the (1-2)th frame portion 112, and a third first frame portion (hereinafter, will be referred to as “(1-3)th frame portion”) 113.

The (1-3)th frame portion 113 may be arranged below the (1-1)th frame portion 111. The (1-3)th frame portion 113 may support the (1-1)th frame portion 111. The (1-3)th frame portion 113 may include a material different from that of the (1-1)th frame portion 111, and may include a same material as that of the (1-2)th frame portion 112. In an embodiment, for example, the (1-3)th frame portion 113 may include the second material, e.g., silicon silicide (SiNₓ).

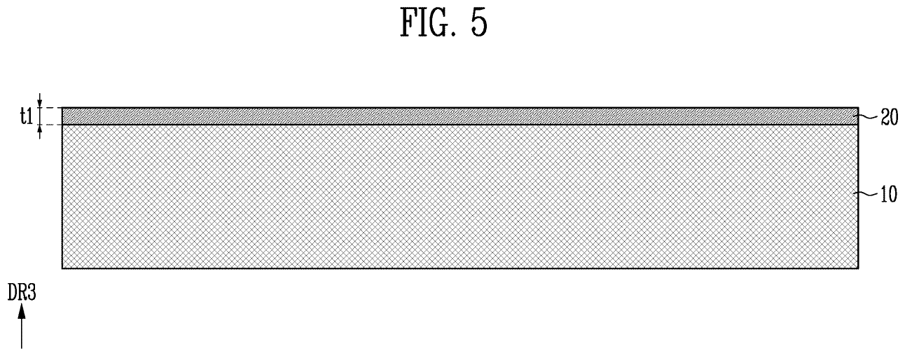

FIGS. 5 to 10 are diagrams illustrating a method of manufacturing a mask according to an embodiment. FIGS. 5 to 10 schematically show an embodiment of a method of manufacturing the mask 100 shown in FIG. 2.

Referring to FIG. 5, in an embodiment of a method of manufacturing a mask, a layer 20 is formed on a base substrate 10. The base substrate 10 may include silicon (Si). In an embodiment, for example, the base substrate 10 may be a silicon wafer. The layer 20 may include silicon nitride (SiNₓ). A thickness t1 of the layer 20 formed on the base substrate 10 may be about 1 micrometer (μm) or less. The thickness t1 may be a length measured in the third direction DR3.

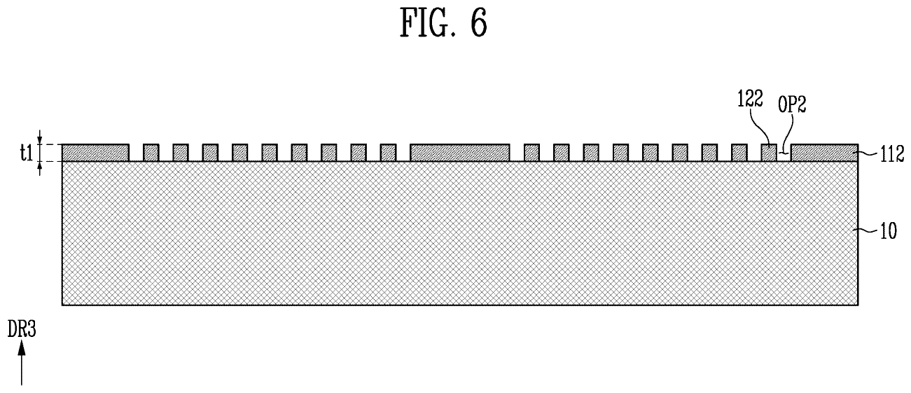

Referring to FIG. 6, the layer 20 (see FIG. 5) is etched to form the (1-2)th frame portion 112 and (2-2)th frame portions 122. That is, the layer 20 may be patterned into the (1-2)th frame portion 112 and the (2-2)th frame portions 122 by etching. In an embodiment, for example, the layer 20 may be etched by a dry etching method, but embodiments are not necessarily limited thereto. The (2-2)th frame portions 122 may be patterned in a lattice (or mesh) pattern to include the second openings OP2. The thickness t1 of each of the (1-2)th frame portion 112 and the (2-2)th frame portions 122 may be about 1 μm or less.

Referring to FIG. 7, the base substrate 10 is etched to form patterns 10a. In an embodiment, for example, the patterns 10a are patterned by etching an upper surface of the base substrate 10 overlapping the second openings OP2 of the (2-2)th frame portions 122 (see FIG. 6). In an embodiment, for example, the base substrate 10 may be etched by a dry etching method, but embodiments are not necessarily limited thereto. Widths of the patterns 10a in a cross-section may increase as being away from the (1-2)th frame portion 112 in the third direction DR3 (or a thickness direction). In an embodiment, for example, each of the patterns 10a in cross-section may have an inverted tapered shape. In an embodiment, for example, a thickness t2 of each of the patterns 10a may be about 1 μm or greater, i.e., greater than or equal to about 1 μm. In an embodiment, for example, an inverted taper angle θ of each of the patterns 10 a may be greater than about 90°. The inverted taper angle θ may be an internal angle of each of the patterns 10a having an inverted tapered shape in a cross-section.

A bond strength (325 kilojoules per mole (kJ/mol)) between silicon (Si) and silicon (Si) is smaller than a bond strength (799.6 kJ/mol) between silicon (Si) and oxygen (O) and a bond strength (470.0 kJ/mol) between silicon (Si) and nitrogen (N). Therefore, it may be easy to form the patterns 10a having the above-described specifications (i.e., the inverted tapered shape and the inverted taper angle) by etching the base substrate 10 including silicon (Si), in which silicon oxide (SiOₓ) and silicon nitride (SiNₓ) are not included.

In addition, since the patterns 10a are formed using the base substrate 10 including silicon (Si), the degree of warpage may be reduced or maintained even when the thickness t2 of each of the patterns 10a increases. Therefore, the thickness t2 of each of the patterns 10a may be increased to improve the strength of the mask 100 (see FIG. 2). If the patterns 10a are formed by etching the base substrate 10 including silicon oxide (SiOₓ) and/or silicon nitride (SiNₓ), as the thickness t2 of each of the patterns 10a increases, the degree of warpage increases, and the quality and strength of the mask 100 may decrease. That is, in embodiments, the base substrate 10 includes silicon (Si) and may not include silicon oxide (SiOₓ) and silicon nitride (SiNₓ).

The inverted tapered shape of each of the patterns 10a may be formed through the Bosch Process. In an embodiment, for example, sulfur hexafluoride (SF₆) gas and bias are applied to isotropically etch the base substrate 10, octafluorocyclobutane (C₄F₈) gas is applied to form a protective layer 10b, and sulfur hexafluorine (SF₆) gas is applied to anisotropically etch the base substrate 10. The above processes may then be repeated to form the patterns 10a having an inverted tapered shape. Accordingly, a protective layer 10b having an irregular structure may be formed on the patterns 10a having an inverted tapered shape. However, the embodiments are not necessarily limited thereto.

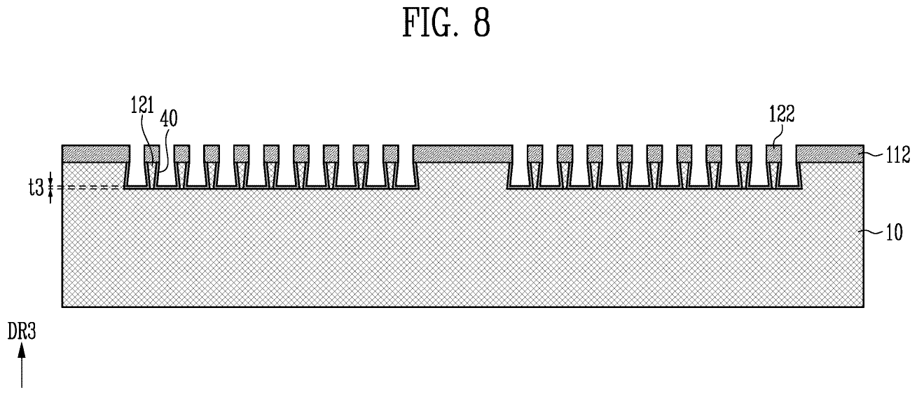

Referring to FIG. 8, the patterns 10a (see FIG. 7) and an oxide layer 40 are formed on the base substrate 10. In an embodiment, for example, the oxide layer 40 may be formed by a wet oxidation method. In an embodiment, for example, the oxide layer 40 may be formed by supplying water vapor (H₂O) to the patterns 10a including silicon (Si) and the base substrate 10. The oxide layer 40 may be a silicon oxide layer (SiO₂). Silicon (Si) on the surface of each of the patterns 10a may react to water vapor (H₂O) to form a silicon oxide layer (SiO₂) and the (2-1)th frame portions 121. In an embodiment, for example, the surface of each of the patterns 10a may be turned into a silicon oxide layer (SiO₂) to form (2-1)th frame portions 121 having an inverted tapered shape. Accordingly, widths of upper surfaces of the patterns 10a may be reduced by as much as the portion where the oxide layer 40 is formed, such that widths of upper surfaces of the (2-1)th frame portions 121 may be smaller than those of the upper surfaces of the patterns 10a as shown in FIG. 7. Accordingly, the widths of the upper surfaces of the (2-1)th frame portions 121 facing lower surfaces of the (2-2)th frame portions 122 may be smaller than those of lower surfaces of the (1-2)th frame portions 122. Even after the oxide layer 40 is formed, the inverted taper angle θ (see FIG. 7) of each of the (2-1)th frame portions 121 may be constant.

The oxide layer 40 may surround side surfaces of the (2-1)th frame portions 121. In an embodiment, for example, the oxide layer 40 may be in contact with the side surfaces of the (2-1)th frame portions 121 and may not be in contact with the lower surfaces of the (2-2)th frame portions 121. In an embodiment, for example, the oxide layer 40 may be arranged on the side surfaces of the (2-1)th frame portions 121 having an inverted tapered shape, and may not be arranged on the upper surfaces and the lower surfaces of the (2-1)th frame portions 121. A thickness t3 of the oxide layer 40 may be between about 1000 Angstroms (Å) and about 10000 Å, i.e., in a range of about 1000 Å to about 10000 Å.

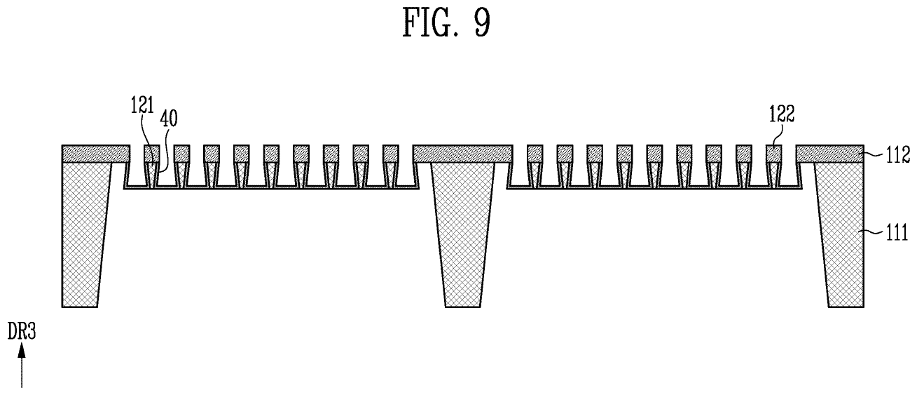

Referring to FIG. 9, a lower surface of the base substrate 10 (see FIG. 8) is etched to form the (1-1)th frame portion 111.

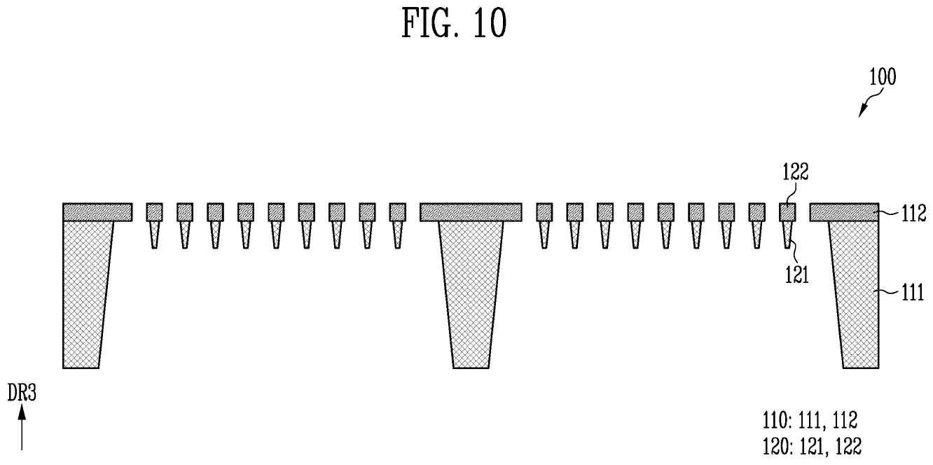

Referring to FIG. 10, the oxide layer 40 (see FIG. 9) may be removed to finally manufacture the mask 100.

FIGS. 11 to 13 are diagrams illustrating a method of manufacturing the mask 100′ according to an embodiment. FIGS. 11 to 13 schematically show an embodiment of a method of manufacturing the mask 100′ shown in FIG. 3. When the mask 100′ shown in FIG. 3 is manufactured, the processes described in FIGS. 5 to 7 may be performed, and any repetitive detailed description thereof will be omitted or simplified.

Referring to FIG. 11, in an embodiment of a method of manufacturing the mask 100′, the patterns 10a (see FIG. 7) and an oxide layer 40′ are formed on the base substrate 10. In an embodiment, for example, the surface of each of the patterns 10a may be turned into a silicon oxide layer (SiO₂) to form (2-1)th frame portions 121′ having an inverted triangle shape. In such an embodiment, the oxide layer 40′ may become thicker than the oxide layer 40 shown in FIG. 8 by adjusting the process conditions for wet oxidation. In an embodiment, for example, the supply amount of water vapor (H₂O) and/or the oxidation temperature may be increased to form the oxide layer 40′ having a large thickness, but the embodiments are not necessarily limited thereto. A thickness t3′ of the oxide layer 40′ may be greater than the thickness t3 of the oxide layer 30 as shown in FIG. 8. In addition, widths of upper surfaces of the (2-1)th frame portions 121′ may be smaller than the widths of upper surfaces of the (2-1)th frame portions 121 as shown in FIG. 8. Even after the oxide layer 40′ is formed, the inverted taper angle θ (see FIG. 7) of each of the (2-1)th frame portions 121′ may be constant. The oxide layer 40′ may surround side surfaces and lower surfaces of the (2-1)th frame portions 121′. In an embodiment, for example, the oxide layer 40′ may be in contact with the side surfaces and the lower surfaces of the (2-1)th frame portions 121′. In an embodiment, for example, the oxide layer 40′ may be arranged on the side surfaces and the lower surfaces of the (2-1)th frame portions 121′ having an inverted triangle shape. The (2-1)th frame portions 121′ may be spaced apart from the base substrate 10 by the oxide layer 40′.

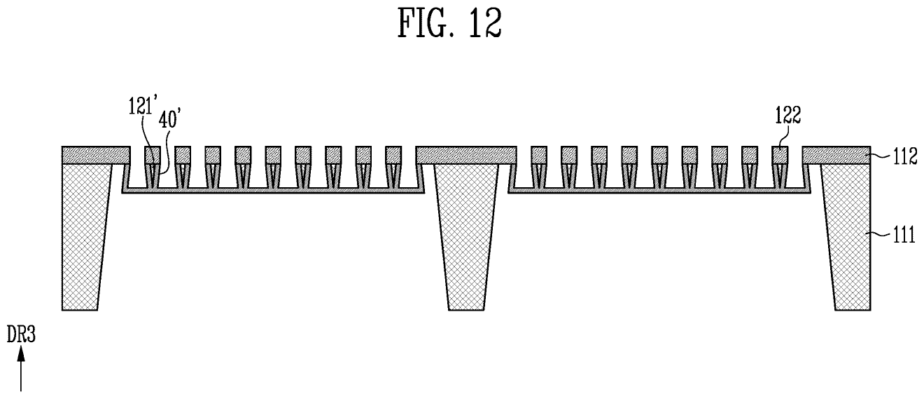

Referring to FIG. 12, the lower surface of the base substrate 10 (see FIG. 11) is etched to form the (1-1)th frame portion 111.

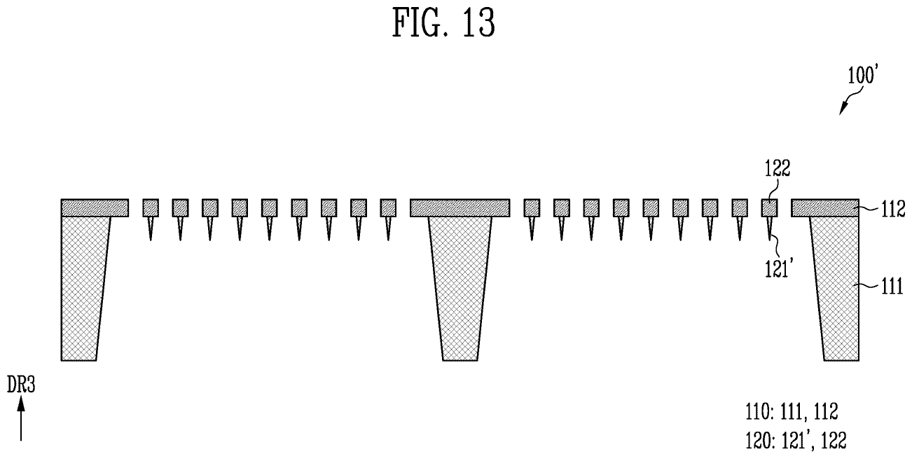

Referring to FIG. 13, the oxide layer 40′ (see FIG. 12) may be removed to finally manufacture the mask 100′.

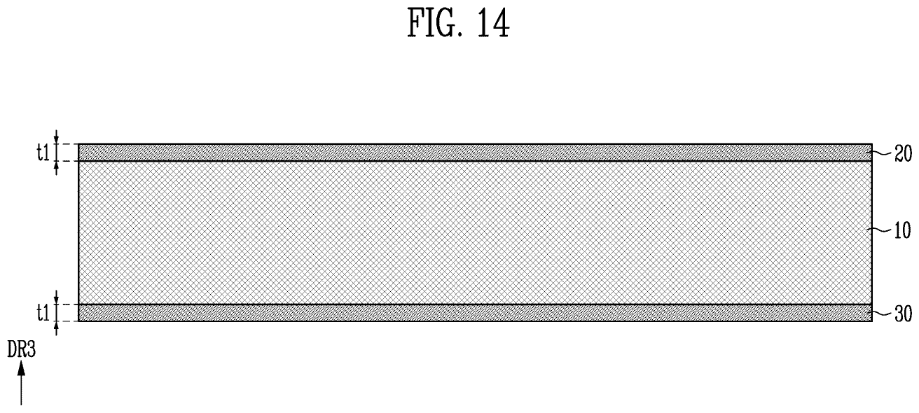

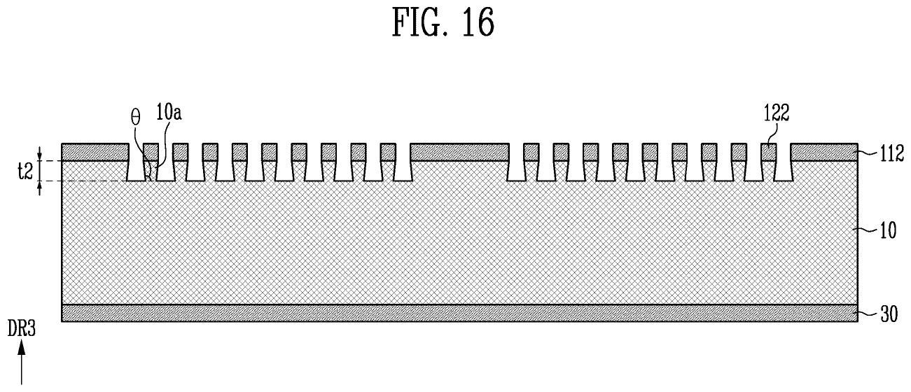

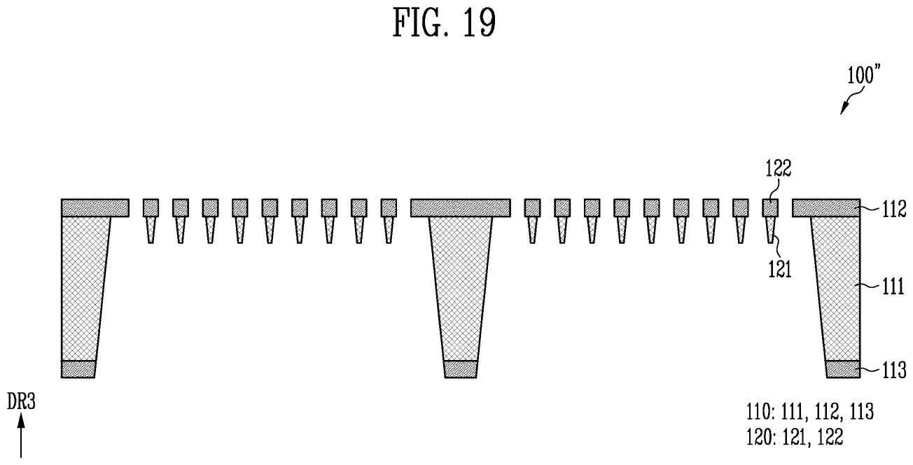

FIGS. 14 to 19 are diagrams illustrating a method of manufacturing a mask according to an embodiment. FIGS. 14 to 19 schematically show an embodiment of a method of manufacturing the mask 100″ shown in FIG. 4. Hereinafter, the same or like elements shown in FIGS. 14 and 19 are labeled with the same reference characters as used above, any repetitive detailed description thereof will be omitted or simplified.

Referring to FIG. 14, the layer 20 (or a first layer) is formed on the base substrate 10, and a layer 30 (or a second layer) is formed under the base substrate 10. The second layer 30 may include the same material as the first layer 20 and may include a different material from the base substrate 10. In an embodiment, for example, the second layer 30 may include a second material, that is, a silicon silicide (SiNₓ). As a result, a sandwich structure of silicon nitride (SiNx)-silicon (Si)-silicon nitride (SiNₓ) may be formed. The second layer 30 may have a same thickness t1 as the first layer 20.

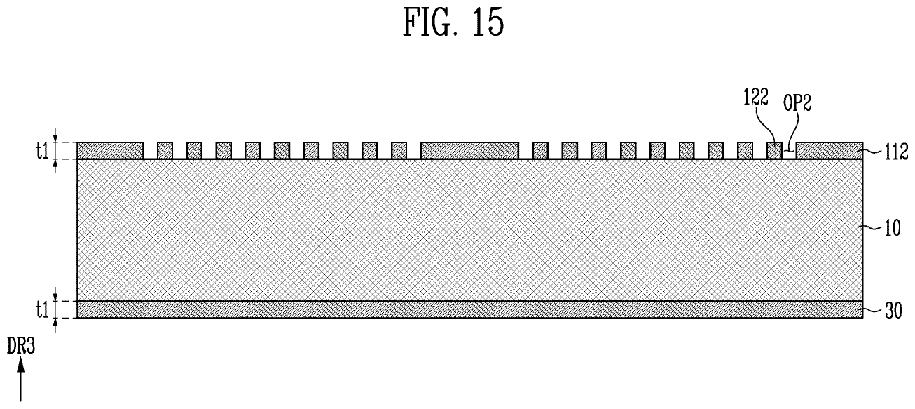

The processes shown in FIGS. 15 to 17 may then be performed sequentially. The processes shown in FIGS. 15 to 17 may be performed in the same manner as the processes described in FIGS. 6 to 8 except that the second layer 30 is formed under the base substrate 10.

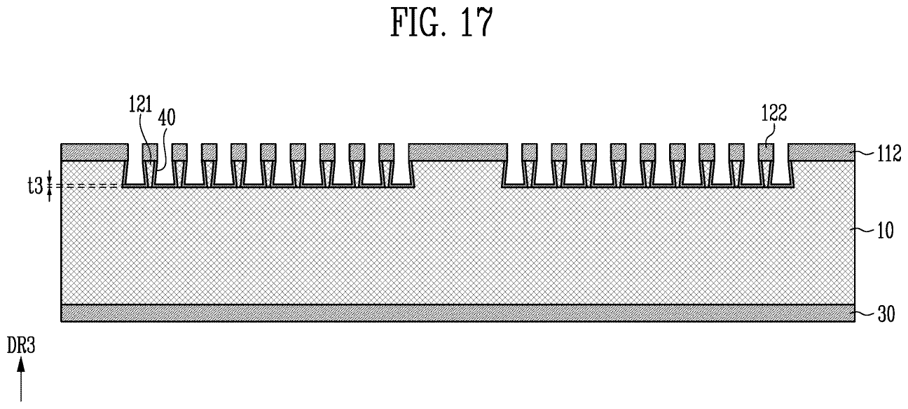

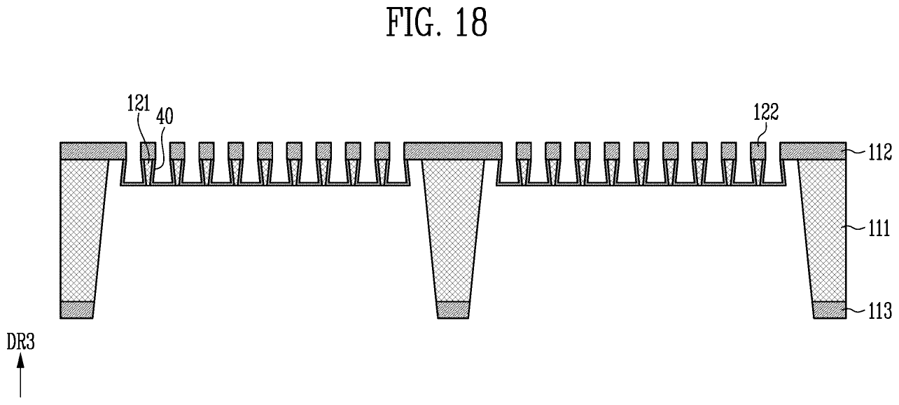

Referring to FIG. 18, a lower surface of the second layer 30 (see FIG. 17) and the lower surface of the base substrate 10 (see FIG. 17) are etched to form the (1-1)th frame portion 111 and the (1-3)th frame portion 113 arranged under the (1-1)th frame portion 111.

Referring to FIG. 19, the oxide layer 40 (see FIG. 18) may be removed to finally manufacture the mask 100″.

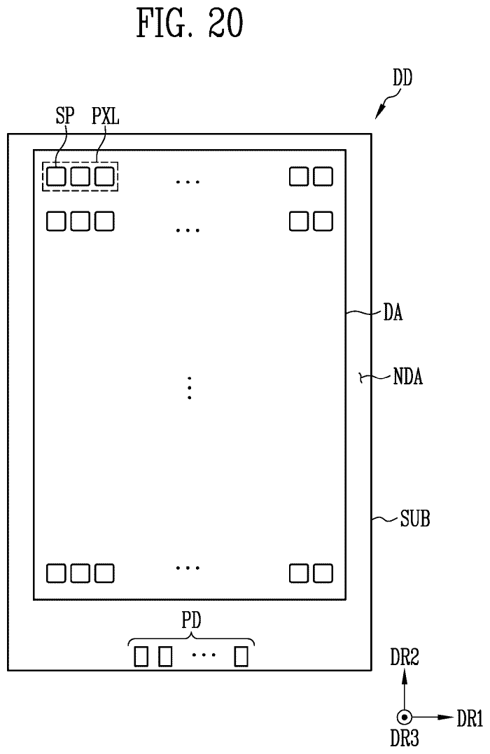

FIG. 20 is a plan view of a display device DD according to an embodiment. The display device DD of FIG. 20 may be manufactured using an embodiment of the mask 100, 100′, or 100″ described above.

Referring to FIG. 20, an embodiment of the display device DD may include a display area DA and a non-display area NDA. The display device DD displays an image through the display area DA. The non-display area NDA is arranged around the display area DA.

The display device DD may include a base layer SUB, sub-pixels SP, and/or pads PD.

The sub-pixels SP are arranged in the display area DA on the base layer SUB. The sub-pixels SP may be arranged in a matrix form in a first direction DR1 and a second direction DR2 intersecting the first direction DR1. However, embodiments are not limited thereto. In an embodiment, for example, the sub-pixels SP may be arranged in a zigzag pattern in the first direction DR1 and the second direction DR2. In an embodiment, for example, the sub-pixels SP may be arranged in a pentile pattern. The first direction DR1 may be a row direction, and the second direction DR2 may be a column direction. Two or more sub-pixels among the sub-pixels SP may constitute one pixel PXL.

A component for controlling the sub-pixels SP may be arranged in the non-display area NDA on the base layer SUB. In an embodiment, for example, wirings, such as gate lines and data lines, connected to the sub-pixels SP may be arranged in the non-display area NDA.

Pads PD are placed in the non-display area NDA on the base layer SUB. The pads PD may be electrically connected to the sub-pixels SP through the wirings. In an embodiment, for example, the pads PD may be connected to the sub-pixels SP through the data lines.

Voltages and signals used for operations of components included in the display device DD may be provided from a driver integrated circuit through the pads PD. In an embodiment, for example, the data lines may be connected to the driver integrated circuit via the pads PD. In an embodiment, for example, power supply voltages may be received from the driver integrated circuit via the pads PD.

The circuit board may be electrically connected to the pads PD using a conductive adhesive member such as an anisotropic conductive layer. The circuit board may be a flexible circuit board or a flexible film having a flexible material. The driver integrated circuit may be mounted on a circuit board and electrically connected to the pads PD.

The display area DA may have various shapes. The display area DA may have the shape of a closed loop including straight and/or curved sides. In an embodiment, for example, the display area DA may have shapes such as a polygon, a circle, a semicircle, and an ellipse in a plan view or when viewed in the third direction DR3. Here, the third direction DR3 may be a thickness direction of the display device DD.

The display device DD may have a flat display surface. However, the embodiments are not necessarily limited thereto. In an embodiment, for example, the display device DD may have an at least partially round display surface. The display device DD may be bendable, foldable, or rollable. The display device DD and/or the base layer SUB may include materials having a flexible property.

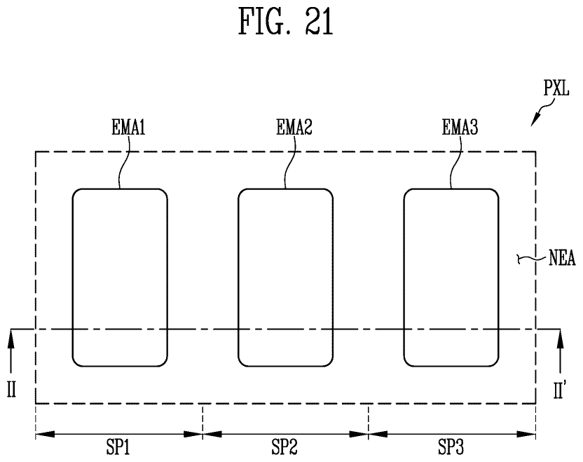

FIG. 21 is a plan view of first to third sub-pixels SP1 to SP3 according to an embodiment.

Referring to FIG. 21, in an embodiment, the pixel PXL may include the first to third sub-pixels SP1 to SP3 arranged in the first direction DR1.

The first sub-pixel SP1 may include a first emission area EMA1 and a non-emission area NEA around the first emission area EMA1. The second sub-pixel SP2 may include a second emission area EMA2 and the non-emission area NEA around the second emission area EMA2. The third sub-pixel SP3 may include a third emission area EMA3 and the non-emission area NEA around the third emission area EMA3.

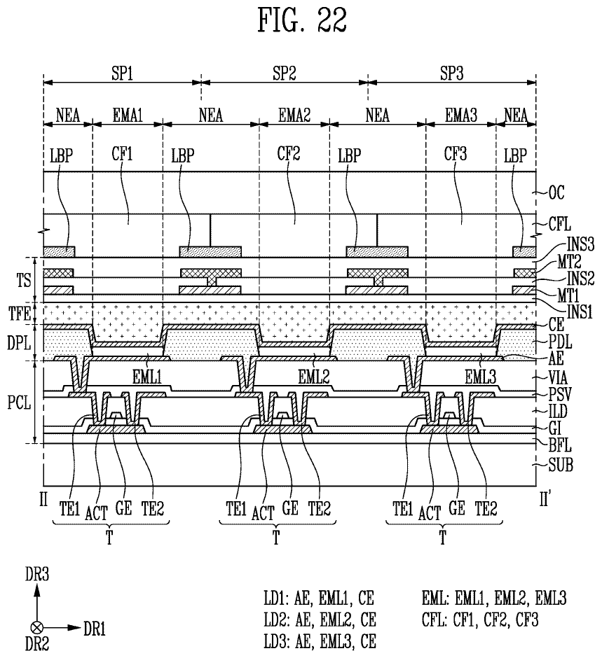

The first emission area EMA1 may be an area to which light is emitted from a first emission layer EML1 (see FIG. 22) of the first sub-pixel SP1. The second emission area EMA2 may be an area to which light is emitted from a second emission layer EML2 (see FIG. 22) of the second sub-pixel SP2. The third emission area EMA3 may be an area to which light is emitted from the third emission layer EML3 (see FIG. 22) of the third sub-pixel SP3.

FIG. 22 is a cross-sectional view taken along line II-II′ of FIG. 21.

Referring to FIG. 22, the first, second, and third sub-pixels SP1, SP2, and SP3 include the first, second, and third emission areas EMA1, EMA2, and EMA3, respectively, and the non-emission area NEA may be positioned between the first, second, and third emission areas EMA1, EMA2 and EMA3 of the first to third sub-pixels SP1 to SP3.

Each of the first to third sub-pixels SP1 to SP3 may include a pixel circuit layer PCL, a display device layer DPL, and/or a thin film encapsulation layer TFE which are sequentially arranged on the base layer SUB.

The base layer SUB may form or provide a base surface. The base layer SUB may include a transparent insulating material to transmit light. The base layer SUB may be a rigid substrate or a flexible substrate. The rigid substrate may be, for example, one of a glass substrate, a quartz substrate, a glass ceramic substrate, and a crystalline glass substrate. The flexible substrate may be one of a film substrate containing a polymer organic material and a plastic substrate. In an embodiment, for example, the flexible substrate may include, but is not necessarily limited to, at least one selected from polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. In an embodiment, for example, the base layer SUB may be a substrate including silicon. According to an embodiment, the display device DD may be an OLED on silicon (OLEDoS) display device including a display panel formed on a silicon substrate.

The pixel circuit layer PCL may include a buffer layer BFL, a gate insulating layer GI, an interlayer insulating layer ILD, a passivation layer PSV, and/or a via layer VIA which are sequentially stacked on the base layer SUB in the third direction DR3.

The buffer layer BFL may be an inorganic insulating layer including an inorganic material. The buffer layer BFL may include at least one selected from metal oxides such as silicon nitride (SiNx), silicon oxide (SiOx), silicon oxynitride (SiOxNy), and aluminum oxide (AlOx). The buffer layer BFL may be provided as a single layer, but may also be provided as multiple layers of at least a double layer. In an embodiment where the buffer layer BFL is provided as multiple layers, the respective layers may include a same material as or different materials from each other. In another embodiment, the buffer layer BFL may be omitted, depending on the material and process conditions of the base layer SUB.

A transistor T may be arranged on the buffer layer BFL. The transistor T may include an active pattern ACT, a gate electrode GE, a first transistor electrode TE1, and/or a second transistor electrode TE2.

The active pattern ACT may be arranged on the buffer layer BFL. The active pattern ACT may include a polysilicon semiconductor. In an embodiment, for example, the active pattern ACT may be formed through a low temperature polysilicon process. However, the present invention is not necessarily limited thereto, and the active pattern ACT may include an oxide semiconductor, a metal oxide semiconductor, or the like.

The active pattern ACT may include a channel region, a first contact region connected to one end of the channel region, and a second contact region connected to an opposing end of the channel region. The channel region, the first contact region, and the second contact region may include a semiconductor layer which is or is not doped with impurities. In an embodiment, for example, the first contact region and the second contact region may include an impurity-doped semiconductor layer, and the channel region may include a semiconductor layer which is not doped with impurities. As the impurities, for example, a p-type impurity may be used, but is not limited thereto. One of the first and second contact regions may be a source region and the other may be a drain region.

The gate insulating layer GI may be arranged on the active pattern ACT. The gate insulating layer GI may be an inorganic layer (or an inorganic insulating layer) including an inorganic material. In an embodiment, for example, the gate insulating layer GI may include at least one selected from metal oxides such as silicon nitride (SiNx), silicon oxide (SiOx), silicon oxynitride (SiOxNy), and aluminum oxide (AlOx). However, the material of the gate insulating layer GI is not limited to the above-described embodiments. According to an embodiment, the gate insulating layer GI may include an organic layer (or an organic insulating layer) including an organic material. The gate insulating layer GI may be provided as a single layer, but may also be provided as multiple layers of at least a double layer.

The gate electrode GE may be arranged on the gate insulating layer GI. The gate electrode GE may overlap a channel region of the active pattern ACT in the third direction DR3. The gate electrode GE may include a single layer including at least one selected from copper (Cu), molybdenum (Mo), tungsten (W), aluminum neodymium (AlNd), titanium (Ti), aluminum (Al), silver (Ag), and alloys thereof, or a double-layer structure or a multi-layer structure of a low-resistance material such as molybdenum (Mo), titanium (Ti), copper (Cu) aluminum (Al), or silver (Ag) to reduce wiring resistance.

The interlayer insulating layer ILD may be arranged on the gate electrode GE. The interlayer insulating layer ILD may include a same material as the gate insulating layer GI or may include one or more materials selected from the materials listed above as constituent materials of the gate insulating layer GI.

The first transistor electrode TE1 and the second transistor electrode TE2 may be arranged on the interlayer insulating layer ILD. The first transistor electrode TE1 of the transistor T may be in contact with the first contact region of the active pattern ACT through a contact hole penetrating the interlayer insulating layer ILD and the gate insulating layer GI. In an embodiment where the first contact region is a source region, the first transistor electrode TE1 may be a first source electrode.

The second transistor electrode TE2 of the transistor T may be in contact with the second contact region of the opposing end of the active pattern ACT through a contact hole defined through the interlayer insulating layer ILD and the gate insulating layer GI. When the second contact region is a drain region, the second transistor electrode TE2 may be a second drain electrode.

The first transistor electrode TE1 and the second transistor electrode TE2 may include the same material as the gate electrode GE or may include one or more materials selected from the materials listed above as constituent materials of the gate electrode GE.

The passivation layer PSV may be arranged on the first transistor electrode TE1 and the second transistor electrode TE2. The passivation layer PSV (e.g., a protective layer) may be an inorganic layer (or an inorganic insulating layer) containing an inorganic material or an organic layer (or an organic insulating layer) containing an organic material. The inorganic layer may include, for example, at least one of metal oxides such as silicon oxide (SiOx), silicon nitride (SiNx), silicon oxynitride (SiOxNy), and aluminum oxide (AlOx). The organic layer may include, for example, at least one selected from a polyacrylates resin, an epoxy resin, a phenolic resin, a polyamide resin, a polyimide resin, an unsaturated polyester resin, a polyphenylene ethers resin, a polyphenylene sulfides resin, and a benzocyclobutene resin.

The passivation layer PSV may include a same material as the interlayer insulating layer ILD, but embodiments are not necessarily limited thereto. The passivation layer PSV may be provided as a single layer, but may also be provided as multiple layers of at least a double layer.

A via layer VIA may be arranged on the passivation layer PSV. The via layer VIA may include a same material as the passivation layer PSV or may include one or more materials selected from the materials exemplified as constituent materials of the passivation layers (PSV). In an embodiment, the via layer VIA may be an organic layer including an organic material.

The display device layer DPL may be arranged on the pixel circuit layer PCL. The display device layer DPL may include a light-emitting device LD which emits light. The first to third sub-pixels SP1 to SP3 may include first to third light-emitting devices LD1 to LD3, respectively.

The first light-emitting device LD1 may include an anode AE, the first emission layer EML1, and a cathode CE. The second light-emitting device LD2 may include the anode AE, a second emission layer EML2, and the cathode CE. The third light-emitting device LD3 may include the anode AE, and the third light-emitting device LD3 may include the anode AE, the third light-emitting device LD3, and the cathode CE. For example, the first to third light-emitting devices LD1 to LD3 may be top emission organic light-emitting devices.

The anodes AE of the respective sub-pixels SP are arranged in the emission areas EMA1, EMA2, and EMA3, and may be spaced apart from each other. The anode AE of each of the sub-pixels SP may be electrically connected to the first transistor electrode TE1 of the transistor T of each sub-pixel SP through a contact hole defined through the via layer VIA and the passivation layer PSV.

A bank PDL may be placed on the anode AE. The bank PDL may define (or partition) the emission areas EMA1, EMA2, and EMA3 of the respective sub-pixels SP. The bank PDL may include an opening which partially exposes the anode AE of each sub-pixel SP.

The bank PDL may be an organic insulating layer including an organic material. Examples of the organic material may include acryl resins, epoxy resins, phenolic resins, polyamide resins, polyimide resins, and the like. However, the present disclosure is not limited thereto, and the bank PDL may be an inorganic insulating layer including an inorganic material.

According to an embodiment, the bank PDL may include a light absorbing material or a light absorbing agent may be applied to absorb light introduced from the outside. In an embodiment, for example, the bank PDL may include carbon-based black pigments. However, the present invention is not necessarily limited thereto, and the bank PDL may include an opaque metal material such as chromium (Cr), molybdenum (Mo), an alloy (MoTi) of molybdenum (Mo) and titanium (Ti), tungsten (W), vanadium (V), niobium (Nb), tantalum (Ta), manganese (Mn), cobalt (Co), or nickel (Ni) having a high light absorption rate.

An emission layer EML of each sub-pixel SP may be arranged on the anode AE exposed by the bank PDL. The cathode CE may be arranged on the emission layer EML. The cathode CE may be arranged across all of the first to third sub-pixels SP1 to SP3. In an embodiment, for example, the cathode CE may be provided as a common electrode, but is not necessarily limited thereto.

The cathode CE may include metal layers such as silver (Ag), magnesium (Mg), aluminum (Al), platinum (Pt), palladium (Pd), gold (Au), nickel (Ni), neodymium (Nd), iridium (Ir), chromium (Cr), and alloys thereof, and/or transparent conductive layers such as indium tin oxide (ITO), indium zinc oxide (IZO), zinc oxide (ZnO), and indium tin zinc oxide (ITZO). Depending on embodiments, the cathode CE may include multiple layers of at least a double layer including a thin metal layer, for example, a triple layer of ITO/Ag/ITO.

The thin film encapsulation layer TFE may be arranged on the display device layer DPL. The thin film encapsulation layer TFE may have a single layer structure or a multilayer structure. The thin film encapsulation layer TFE may include an insulating layer covering the light-emitting device LD. The thin film encapsulation layer TFE may include at least one inorganic layer and at least one organic layer. In an embodiment, for example, the thin film encapsulation layer TFE may have a structure in which inorganic layers and organic layers are alternately stacked. In an embodiment, for example, the thin film encapsulation layer TFE may include a first inorganic layer, an organic layer arranged on the first inorganic layer, and a second inorganic layer arranged on the organic layer.

A sensing layer TS may be arranged on the thin film encapsulation layer TFE. The sensing layer TS may include a first insulating layer INS1, a first conductive layer MT1, a second insulating layer INS2, a second conductive layer MT2, and/or a third insulating layer INS3.

The first insulating layer INS1 may be arranged on the thin film encapsulation layer TFE. The first insulating layer INS1 may be an inorganic insulating layer including an inorganic material. The inorganic insulating layer may include an inorganic insulating material such as silicon oxide (SiOx), silicon nitride (SiNx), silicon oxynitride (SiOxNy), aluminum oxide (AlxOy), titanium oxide (TiOx), tantalum oxide (TaxOy), hafnium oxide (HfOx), or zinc oxide (ZnOx). According to an embodiment, the first insulating layer INS1 may be omitted or may be configured as an uppermost layer of the thin film encapsulation layer TFE.

The first conductive layer MT1 may be arranged on the first insulating layer INS1. The first conductive layer MT1 may be partially opened so as not to overlap the light-emitting device LD of each sub-pixel SP. In an embodiment, for example, the first conductive layer MT1 may be arranged to overlap the non-emission area NEA around the emission areas EMA1, EMA2, and EMA3.

The first conductive layer MT1 may include a metal layer or a transparent conductive layer. In an embodiment, for example, the metal layer may include at least one selected from molybdenum, titanium, copper, aluminum, and alloys thereof. The transparent conductive layer may include, but is not necessarily limited to, one of indium tin oxide (ITO), indium zinc oxide (IZO), zinc oxide (ZnO), indium tin zinc oxide (ITZO), PEDOT, or metal nanowires. The first conductive layer MT1 may form a connection electrode connecting sensing electrodes.

The second insulating layer INS2 may be arranged on the first conductive layer MT1. The second insulating layer INS2 may include the same material as the above-described first insulating layer INS1, or may include one or more materials selected from materials listed above as constituent materials of the first insulating layer INS1.

The second conductive layer MT2 may be arranged on the second insulating layer INS2. The second conductive layer MT2 may be partially opened not to overlap the light-emitting device LD of each sub-pixel SP. In an embodiment, for example, the second conductive layer MT2 may be arranged to overlap the non-emission area NEA around the emission areas EMA1, EMA2, and EMA3.

The second conductive layer MT2 may include the same material as the above-described first conductive layer MT1, or may include one or more materials selected from materials exemplified as constituent materials of the first conductive layer MT1.

The second conductive layer MT2 may be electrically connected to the first conductive layer MT1 through a contact hole defined through the second insulating layer INS2. The second conductive layer MT2 may form sensing electrodes.

The third insulating layer INS3 may be arranged on the second conductive layer MT2. The third insulating layer INS3 may be an organic insulating layer including an organic material. However, the present disclosure is not necessarily limited thereto, and according to an embodiment, the third insulating layer INS3 may include an inorganic layer or may have a structure in which an organic layer and an inorganic layer are alternately stacked.

A light shielding layer LBP may be arranged on the display device layer DPL, the thin film encapsulation layer TFE, and/or the sensing layer TS. The light shielding layer LBP may include an opening overlapping the light-emitting device LD. In an embodiment, for example, the light shielding layer LBP may be arranged to overlap the non-emission area NEA around the emission areas EMA1, EMA2, and EMA3.

The light shielding layer LBP may include a light shielding material to prevent light leakage and color mixing defects. In an embodiment, for example, the light blocking layer LBP may include, but is not necessarily limited to, a black matrix. According to an embodiment, the light shielding layer LBP may include carbon black (CB) and/or titanium black (TiBK).

A color filter layer CFL may be arranged on the light shielding layer LBP. The color filter layer CFL may include color filters CF1 to CF3 which match the color of the respective sub-pixels SP. By arranging the color filters CF1 to CF3 corresponding to the colors of the first to third sub-pixels SP1 to SP3, respectively, a full-color image may be displayed.

The color filter layer CFL may include a first color filter CF1 arranged in the first sub-pixel SP1 to selectively transmit light emitted from the first sub-pixel SP1, a second color filter CF2 arranged in the second sub-pixel SP2 to selectively transmit light emitted from the second sub-pixel SP2, and a third color filter CF3 arranged in the third sub-pixel SP3 to selectively transmit light emitted from the third sub-pixel SP3.

In an embodiment, the first color filter CF1, the second color filter CF2, and the third color filter CF3 may be a red color filter, a green color filter, and a blue color filter, respectively, but are not necessarily limited thereto.

The first color filter CF1 may include a color filter material which selectively transmits light of a first color (or red). In an embodiment, for example, where the first sub-pixel SP1 is a red sub-pixel, the first color filter CF1 may include a red color filter material.

The second color filter CF2 may include a color filter material which selectively transmits light of a second color (or green). In an embodiment, for example, where the second sub-pixel SP2 is a green sub-pixel, the second color filter CF2 may include a green color filter material.

The third color filter CF3 may include a color filter material which selectively transmits light of a third color (or blue). In an embodiment, for example, where the third sub-pixel SP3 is a blue sub-pixel, the third color filter CF3 may include a blue color filter material.

An overcoat layer OC may be provided on the color filter layer CFL. The overcoat layer OC may include a variety of materials suitable for protecting the underlying layers from foreign materials such as dust, moisture, etc. In an embodiment, for example, the overcoat layer OC may include at least one selected from an inorganic insulating layer and an organic insulating layer. In an embodiment, for example, the overcoat layer OC may include epoxy, but embodiments are not limited thereto.

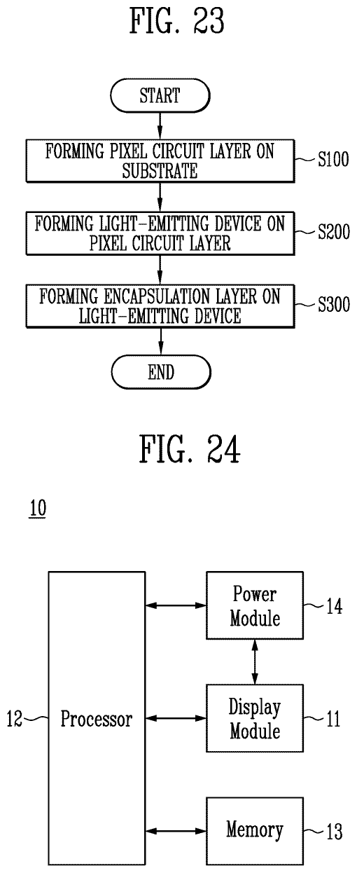

FIG. 23 is a flowchart illustrating a method of manufacturing the display device DD according to an embodiment. The method of manufacturing the display device DD may be a method of manufacturing the display device DD (see FIG. 20) using an embodiment of the mask 100, 100′, or 100″ described above.

Referring to FIG. 23, an embodiment of a method of manufacturing a display device may include forming a pixel circuit layer on a substrate (S100), forming a light-emitting device on the pixel circuit layer (S200), and forming an encapsulation layer on the light-emitting device (S300).

In a process S100 of forming the pixel circuit layer on the substrate, circuit devices may be patterned on the substrate (or the base layer SUB of FIG. 22), and the pixel circuit layer PCL (see FIG. 22) may be provided thereon.

According to an embodiment, the conductive layer, the insulating layer, and the like on the substrate SUB may be formed based on the general processes of manufacturing a semiconductor device. In an embodiment, for example, the conductive layer or the insulating layer on the substrate SUB may be formed by a photolithography process, may be etched by various methods (wet etching, dry etching, etc.), and may be deposited by various methods (sputtering, chemical vapor deposition, etc.). The present disclosure is not necessarily limited to specific examples.

In a process S100 of forming the pixel circuit layer on the substrate, the transistors T (see FIG. 22) may be patterned on the substrate SUB.

In a process S200 of forming a light-emitting device on the pixel circuit layer, the anodes AE (see FIG. 22), the emission layers EML1 to EML3 (see FIG. 22), and the cathode CE (see FIG. 2) may form the first to third light-emitting devices LD1 to LD3 (see FIG. 22).

In a process S200 of forming the light-emitting device on the pixel circuit layer, the anodes AE may be patterned, and the bank PDL (see FIG. 22) overlapping the anodes AE may be patterned.

Subsequently, depositing the first to third emission layers EML1 to EML3 on the anodes AE may be performed. The first to third emission layers EML1 to EML3 may be deposited using an embodiment of the mask 100, 100′, or 100″ described above. In an embodiment, for example, materials for forming the first to third emission layers EML1 to EML3 may pass through the mask 100, 100′, or 100″ and be arranged on the anodes AE. Subsequently, the cathode CE may be formed on the first to third emission layers EML1 to EML3.

In a process S300 of forming the encapsulation layer on the light-emitting device, the encapsulation layer TFE (see FIG. 22) may be formed on the first to third light-emitting devices LD1 to LD3. The underlying layers of the encapsulation layer TFE may be passivated.

The sensing layer TS (see FIG. 22), the light shielding layer LBP (see FIG. 22), and the color filter layer CFL (see FIG. 22) may be arranged according to the embodiment, and the display device DD according to the embodiment may be provided.

FIG. 24 is a block diagram of an electronic device 10 according to an embodiment.

Referring to FIG. 24, the display device DD according to an embodiment (see FIG. 20) is applicable to various types of electronic devices. In an embodiment, the electronic device 10 includes the above-described display device DD and may further include other modules or devices having additional functions in addition to the display device DD. The electronic device 10 may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device DD according to embodiments as described above. In addition, in terms of functionality, some of the individual modules included in one module may be included in the display device DD and others may be provided separately from the display device DD. In an embodiment, for example, the display module 11 is included in the display device, whereas the processor 12, the memory 13, and the power module 14 are not included in the display device DD and are instead provided separately in the electronic device 10.

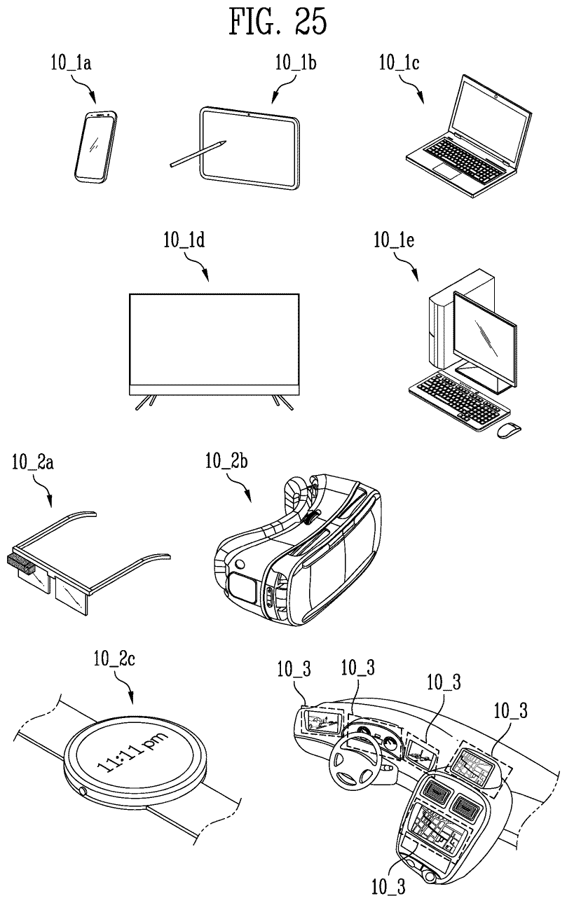

FIG. 25 shows schematic views of various embodiments of an electronic device.

Referring to FIG. 25, various types of electronic devices to which embodiments of the display device DD (FIG. 20) are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

In accordance with embodiments of the invention, a mask that is easy to form an inverted tapered shape and an inverted taper angle, and has an increased strength and a decreased degree of warpage, and a method of manufacturing the mask may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A mask comprising:
a first frame, wherein first openings are defined through the first frame; and
second frames respectively arranged in the first openings, wherein second openings smaller than the first openings are defined through each of the second frames,
wherein the first frame includes: a (1-1)th frame portion; and a (1-2)th frame portion arranged on the (1-1)th frame portion,
wherein each of the second frames includes: a (2-1)th frame portion in a lattice pattern; and a (2-2)th frame portion arranged on the (2-1)th frame portion,
wherein the (1-1)th frame portion and the (2-1)th frame portion include a first material, and
wherein the (1-2)th frame portion and the (2-2)th frame portion include a second material different from the first material.

2. The mask of claim 1, wherein the first material is silicon, and the second material is a silicon nitride.

3. The mask of claim 1, wherein, in a cross-section, the (2-2)th frame portion has a rectangular shape.

4. The mask of claim 1, wherein, in a cross-section, a width of the (2-1)th frame portion increases as being away from the (2-2)th frame portion in a thickness direction of the mask.

5. The mask of claim 4, wherein, in the cross-section, the (2-1)th frame portion has an inverted tapered shape.

6. The mask of claim 5, wherein an inverted taper angle of the (2-1)th frame portion is greater than about 90°.

7. The mask of claim 1, wherein, in a cross-section, the (2-1)th frame portion has an inverted triangle shape.

8. The mask of claim 1, wherein a width of an upper surface of the (2-1)th frame portion facing a lower surface of the (2-2)th frame portion is smaller than a width of the lower surface of the (2-2)th frame portion.

9. The mask of claim 1, wherein a thickness of the (2-1)th frame portion is about 1 μm or greater.

10. The mask of claim 1, wherein a thickness of each of the (1-2)th frame portion and the (2-2)th frame portion is about 1 μm or less.

11. The mask of claim 1, further comprising a third first frame arranged under the third first frame portion, wherein the third first frame includes the second material.

12. A method of manufacturing a mask, the method comprising:
forming a layer on a base substrate;
forming a (1-2)th frame portion and (2-2)th frame portions including openings by etching the layer;
forming patterns having widths increasing as being away from an upper surface of the base substrate in a thickness direction of the base substrate in a cross section by etching the upper surface of the base substrate;
forming (2-1)th frame portions and an oxide layer surrounding the (2-1)th frame portions by oxidizing the patterns;
forming a (1-1)th frame portion by etching a lower surface of the base substrate; and
removing the oxide layer.

13. The method of claim 12, wherein the base substrate includes silicon, and the layer includes a silicon nitride.

14. The method of claim 12, wherein a thickness of the layer is about 1 μm or less.

15. The method of claim 12, wherein a thickness of each of the patterns is about 1 μm or greater.

16. The method of claim 12, wherein the patterns have an inverted tapered shape in a cross section.

17. The method of claim 16, wherein inverted taper angles of the patterns are greater than about 90°.

18. The method of claim 16, wherein the oxide layer surrounds side surfaces of the (2-1)th frame portions.

19. The method of claim 12, wherein, in a cross-section, the patterns have an inverted triangle shape, and
wherein the oxide layer surrounds side surfaces and lower surfaces of the (2-1 )th frame portions.

20. An electronic device comprising:
a processor; and
a display device including an emission layer, wherein the display device displays an image in response to control of the processor,
wherein the emission layer is deposited by the mask of claim 1.
